(19) United States
(12) Patent Application Publication
(10) Pub. No.: US 2006/0220165 A1
(43) Pub. Date: Oct. 5, 2006

(54) Semiconductor device

(76) Inventor: Ichiro Hase, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 10/519,877

(22) PCT Filed: Jul. 15, 2003
(86) PCT No.: PCT/JP03/08982

§ 371 Date: Feb. 17, 2006

(30) Foreign Application Priority Data
Jul. 19, 2002 (JP) 2002-210597

(51) Int. Cl. H01L 31/07

(52) U.S. Cl. 257/471

(57) ABSTRACT

There is provided a semiconductor device capable of ensuring a complete enhancement-mode operation and realizing a power transistor excellent in the low-distortion, high-efficiency performance. On a surface of a substrate (1) composed of single crystal GaAs, a second barrier layer (3) composed of AlGaAs, a channel layer (4) composed of InGaAs, a third barrier layer (12) composed of InGaP and a first barrier layer (11) composed of AlGaAs are stacked in this order, while placing in between a buffer layer (2). Relation of χ₁−χ₃≦0.5*(Eg₃-Eg₁), where χ₁ is electron affinity of the first barrier layer (11), Eg₁ is a band gap of the same, χ₃ is electron affinity of the third barrier layer (12), and Eg₃ is a band gap of the same, is satisfied between the first barrier layer (11) and the third barrier layer (12).

### TECHNICAL FIELD

The present invention relates to a semiconductor device applicable to power amplifiers and so forth.

### BACKGROUND ART

Low-distortion, high-efficiency operation and single positive power supply operation are recent demands for transmission power amplifiers for mobile terminals for mobile communication. The high-efficiency operation herein means an operation with a high power-added efficiency (referred to as PAE, hereinafter) which is defined by a ratio of difference between output power Pₒᵤₜ and input power Pᵢₙ, and supplied DC power P_{dc}. PAE is an important figure of merit for power amplifiers because a larger value of PAE means a smaller power consumption. Reduction in the distortion is also a critical issue because recent mobile terminals based on use of wireless communication system such as CDMA (Code Division Multiple Access) and WCDMA (Wideband CDMA) are in need of more strict specifications with respect to distortion of the power amplifiers. Distortion and efficiency are, however, in a trade-off relation in general, and there is a need of increasing PAE under a given low-distortion condition. This is a meaning of the low-distortion, high-efficiency operation.

On the other hand, the single positive power supply operation contributes to downsizing and cost reduction of the terminals through disusing a negative power generation circuit and drain switch, which have been indispensable for conventional power amplifiers configured using depletion-mode FET (Field Effect Transistor).

HBT (Hetero-junction Bipolar Transistor) is a well-known device for the power amplifiers, capable of satisfying these demands. Improvement of power amplifier characteristics in the HBT application needs an increased current density, but this may result in a problem due to heat generation, or this may need an advanced design for heat dissipation for ensuring the reliability. This raises a public attention on single positive power supply operation using a HFET (Hetero-junction Field Effect Transistor). The HFET herein is a general expression for FETs based on hetero-junction, such as HEMT (High Electron Mobility Transistor) and HIGFET (Heterostructure Insulated-Gate FET). The HFET is capable of realizing a high performance switch, and makes it possible to integrate the power amplifier and the switch.

By the way, it is necessary to realize a complete enhancement-mode HFET, in order to realize the single positive power supply operation and to disuse the negative power generation circuit and drain switch in HFET. The complete enhancement-mode herein means an enhancement-mode operation capable of disusing the drain switch, by virtue of a sufficiently small drain leakage during the OFF state, or more specifically, because only a small current flows between the source and drain in a case where a voltage is applied between the source and drain while keeping zero voltage between the gate and source, wherein a threshold voltage Vₜₕ of as high as 0.5 V or around is necessary in general.

The enhancement-mode HFET realized in a form of conventional Schottky-junction-gate-type HFET having a recessed gate structure, however, raises a first problem of increase in source resistance and ON resistance Rₒₙ due to surface depletion, and a second problem of narrowing a difference between a gate-source forward turn-on voltage Vf and Vₜₕ, due to increased Vₜₕ, making it very difficult to obtain the low-distortion, high-efficiency characteristics.

As an HFET capable of readily realizing the complete enhancement-mode operation, there is known a JPHEMT (Junction Pseudomorphic HEMT) typically disclosed in Japanese Patent Application No. Hei 10-258989.

FIG. 7 shows an exemplary configuration of this sort of conventional JPHEMT. The semiconductor device is typically configured so that, on one surface of a substrate 1 composed of semi-insulating single crystal GaAs, a second barrier layer 3 composed of AlGaAs having an Al composition ratio of 20% or around, a channel layer 4 composed of InGaAs having an In composition ratio of 20% or around, and a first barrier layer 5 composed of AlGaAs having an Al composition ratio of 20% or around are stacked in this order, while placing in between a buffer layer 2 composed of u-GaAs not intentionally doped with any impurities (“u-” indicates that no impurity is added intentionally, the same will apply hereinafter).

The first barrier layer 5 has a region 5a doped with an n-type impurity of high concentration, regions 5b not intentionally doped with any impurities, and a p-type conductive region 5c containing a high concentration of p-type impurity, being provided under the gate electrode 9. The second barrier layer 3 has a region 3a doped with an n-type impurity of high concentration, and regions 3b not intentionally doped with any impurities. The p-type conductive region 5c is generally formed by diffusing Zn.

The first barrier layer 5 has an insulating film 6 formed on the surface thereof opposite to the substrate 1. The insulating film 6 has a plurality of openings formed therein, and there are a source electrode 7, a drain electrode 8 and the gate electrode 9 formed on the first barrier layer 5 exposed in these openings. Under the source electrode 7 and the drain electrode 8, there are low-resistivity layers 10 formed typically by alloying between these electrodes and underlying semiconductor layer, wherein the source electrode 7 and the drain electrode 8 establish an n-type ohmic contact with the first barrier layer 5. The gate electrode 9 establishes a p-type ohmic contact with the first barrier layer 5. The channel layer 4 forms a current path between the source electrode 7 and the drain electrode 8. It is to be noted, although not shown in FIG. 7, some cases may have a cap layer doped with an n-type impurity of high concentration between the first barrier layer 5 and the source electrode 7 or the drain electrode 8.

The JPHEMT structure as shown in FIG. 7 has a larger built-in voltage by virtue of adoption of a p-n junction gate, so that higher voltage can be applied to the gate of JPHEMT than that applicable to a general Schottky-gate-type HFET. In other words, a gate-source forward turn-on voltage Vf can be raised. It is to be understood hereinafter that Vf is defined as a voltage which gives a predetermined value of a gate-source forward current.

Another advantage is that the JPHEMT is less subject to the increase in the source resistance due to surface depletion even in the enhancement-mode device having a positive Vₜₕ, because the p-type conductive area 5c containing a high concentration of p-type impurity is formed as being embedded in the first barrier layer 5.

As described in the above, the JPHEMT shown in FIG. 7 has a structure advantageous for the enhancement-mode operation, but is still insufficient in some aspect in view of realizing the above-described complete enhancement-mode operation. More specifically, no problem will arise so far as the JPHEMT shown in FIG. 7, having a Vf of 1.2 V or around which is larger than those of a general Schottky-type HFET or JFET, is used in the enhancement-mode operation, but the complete enhancement-mode operation needs a Vₜₕ of as high as approximately 0.5 V or above, and it is also necessary to ensure satisfactory characteristics even under higher Vₜₕ taking production tolerance into consideration. The higher Vₜₕ, however, narrows the difference between the Vₜₕ and Vf even for the p-n junction gate, and degrades the PAE performance under the low-distortion condition.

The present invention was conceived in consideration of the above-described problems, and an object thereof is to provide a semiconductor device capable of ensuring the complete enhancement-mode operation as a power transistor, and is excellent in the low-distortion, high-efficiency performance.

### DISCLOSURE OF THE INVENTION

An invention (1) relates to a semiconductor device having a source electrode, a drain electrode, a gate electrode disposed between the source electrode and the drain electrode, and a channel layer composed of a semiconductor which serves as a current path between the source electrode and the drain electrode, which comprises a first barrier layer composed of a semiconductor having a p-type conductive region doped with a p-type impurity of high concentration under the gate electrode, a second barrier layer disposed on the opposite side of the first barrier layer while placing the channel layer in between and is composed of a semiconductor having an electron affinity smaller than that of the channel layer, and a third barrier layer disposed between the first barrier layer and the channel layer and is composed of a semiconductor having an electron affinity smaller than that of the channel layer, wherein a relation below:
χ₁−χ₃≦0.5*(Eg₃−Eg₁) (1)
is satisfied, where χ₁ is electron affinity of the first barrier layer, Eg₁ is a band gap of the same, χ₃ is electron affinity of the third barrier layer, and Eg₃ is a band gap of the same.

In the invention (1), by disposing the third barrier layer which satisfies the relation (1) with respect to the first barrier layer between the first barrier layer and the channel layer, it is made possible to increase barrier height φh against a hole, which relates to the gate-source forward turn-on voltage Vf, and therefore to raise the Vf. This facilitates the complete enhancement-mode operation, disuses any negative power generation circuit or drain switch for configuring power amplifiers, and reduces size and cost of the power amplifiers. The Vf can be raised without excessively increasing the source resistance, and this makes it possible to raise the power-added efficiency under a given low-distortion condition.

In the invention (1), semiconductor materials available for composing the first barrier layer 11 and the third barrier layer 12 may be III-V compound semiconductors based on various combinations containing at least any one of Ga, Al and In as a Group III element, and containing at least either one of As and P as a Group V element. For the first barrier layer 11, GaAs, or AlGaAs having an Al composition ratio of 50% or less, or InGaP can typically be used. For the third barrier layer 12, InGaP and AlGaAs having an Al composition ratio of 50% or more, and also quaternary compounds such as AlInGaP and GaInAsP are available. For the channel layer, InGaAs or GaAs is available. Thickness of the third barrier layer is preferably 20 nm or less in view of obtaining a predetermined threshold voltage Vₜₕ adapted to the enhancement-mode operation. For a special case where the p-type conductive region in the first barrier layer is formed by diffusing p-type impurities, it is preferable that the p-type impurity is prevented from entering the third barrier layer. To ensure the prevention, it is preferable to dispose, in the first barrier layer and in a position more closer to the third barrier layer, a semiconductor layer which contains only one-tenth or less impurity as compared with a maximum impurity concentration of the p-type conductive region, to a thickness of 5 nm or more, for example.

An invention (2) relates to the semiconductor device of the above-described invention (1), further comprising, as being disposed between the third barrier layer and the channel layer, a fourth barrier layer composed of a semiconductor having an electron affinity smaller than that of the channel layer.

Even for a case where the third barrier layer, which satisfies the relation with the first barrier layer, expressed by the relation (1), fails in forming a desirable interface with the channel layer, the invention (2) can successfully avoid this problem by using, for the forth barrier layer, a semiconductor material capable of forming a desirable interface with the channel layer.

In the configuration of the invention (2), AlGaAs or GaAs can typically be used for a material for composing the fourth barrier layer. Considering the relation of the Vₜₕ, the fourth barrier layer is preferably formed so that a total of the thickness thereof with that of the third barrier layer is limited to 20 nm or less.

An invention (3) relates to the semiconductor device of the above-described invention (1), further comprising, as being disposed between the first barrier layer and the gate electrode, a fifth barrier layer composed of a semiconductor having a band gap smaller than that of the first barrier layer, and having a p-type conductive region doped with a p-type impurity of high concentration.

The invention (3) makes it possible to reduce ohmic contact resistance, because Schottky barrier height between the gate metal and the semiconductor in contact with the gate metal is lowered.

In the invention (3), GaAs can typically be used as a semiconductor material for composing the fifth barrier layer.

An invention (4) relates to the semiconductor device of the above-described invention (1), further comprising, as being disposed between the first barrier layer and the third barrier layer, a sixth barrier layer composed of a semiconductor in which the Zn diffusion rate is slower than in the first barrier layer.

For a case where the p-type conductive region in the first barrier layer is formed by diffusing Zn, the invention (4) makes it possible to block the diffusion of Zn doped to the first barrier layer by the sixth barrier layer, and thereby facilitates control of the Zn diffusion.

In the configuration of invention (4), GaAs or AlGaAs can typically be used for a semiconductor material for composing the sixth barrier layer. Considering the relation of the Vₜₕ, the sixth barrier layer is preferably formed so that a total of the thickness thereof with that of the third barrier layer is limited to 25 nm or less.

### BRIEF DESCRIPTION OF THE DRAWINGS

FIG. 1 is a sectional view showing a first embodiment of the semiconductor device of the present invention;

FIG. 2 is a band diagram taken along η axis in FIG. 1;

FIG. 3 is a sectional view showing a second embodiment of the semiconductor device of the present invention;

FIG. 4 is a sectional view showing a third embodiment of the semiconductor device of the present invention;

FIG. 5 is a sectional view showing a fourth embodiment of the semiconductor device of the present invention;

FIG. 6 is a sectional view showing a fifth embodiment of the semiconductor device of the present invention;

FIG. 7 is a sectional view showing a conventional JPHEMT as a semiconductor device described in the related art; and

FIG. 8 is a band diagram taken along η axis in FIG. 7.

### BEST MODES FOR CARRYING OUT THE INVENTION

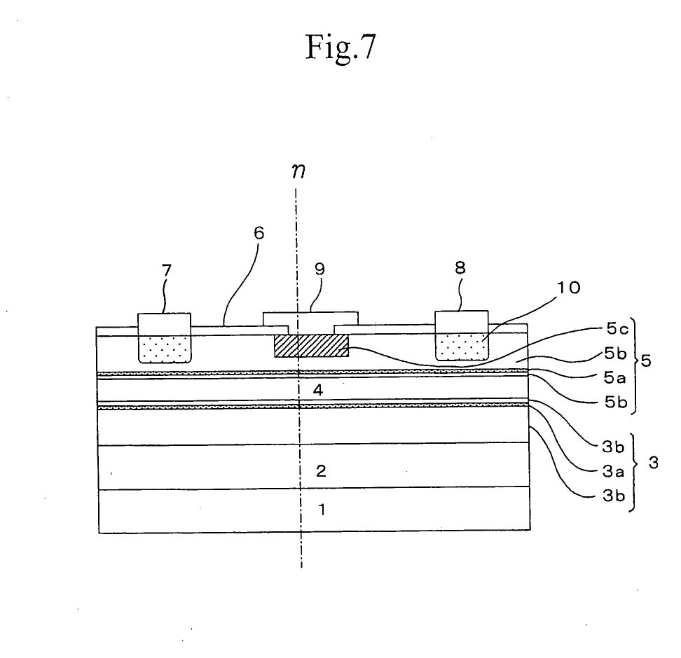

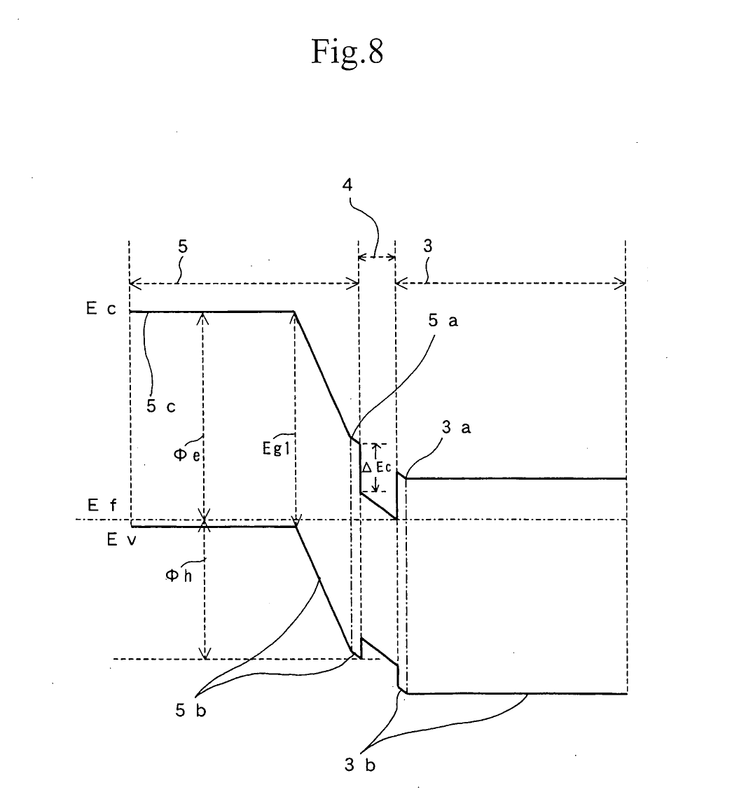

The following paragraphs will describe the embodiments of the present invention. (First Embodiment) To solve the problems in the conventional JPHEMT shown in FIG. 7, the present inventors first carried out a causal analysis on a mechanism of gate leakage. FIG. 8 is a band diagram taken along η axis in FIG. 7, showing a state under absence of gate voltage. Ec is energy at the bottom of a conduction band, Ev is energy at the upper end of a valence band, Ef is the Fermi level, φe is barrier height against electron, and φh is a barrier height against hole. FIG. 8 is based on results obtained from certain specific parameters, and may give other expressions if the parameters vary, but is enough to understand the qualitative tendency described below.

First, it is found from the figure that φe is almost equivalent to the band gap Eg₁ of the first barrier layer 5 (φe˜Eg₁). On the other hand, φh is considerably smaller than Eg₁. The major reason why is that energy difference ΔEc between the conduction band edges of the AlGaAs layer (first barrier layer 5) and the InGaAs layer (channel layer 4) is considerably large, and thus φh<Eg₁−ΔEc holds. ΔEc will be 360 meV or around in a case where an Al composition ratio is 20% or around and an In composition ratio is 20% or around as explained referring to FIG. 7. Because Eg₁ is 1.7 eV or around, φe is consequently given as approximately 1.7 eV, and φh as approximately 1.3 eV. This consequently gives φh<φe, which indicates that the gate forward current is governed by hole injection. Therefore, φh has first to be increased to make gate-source forward turn-on voltage higher.

Increasing of φh may be realized by increasing the Al composition ratio of the first barrier layer, thereby expanding the band gap. In a case of increasing the Al composition ratio typically from 20% or around up to 30 to 40% or around, however, a source contact resistance is generally increased as being expected from a reduced electron affinity. In addition, increasing the Al composition increases the diffusion rate of Zn, and therefore a problem is raised in controllability of the diffusion.

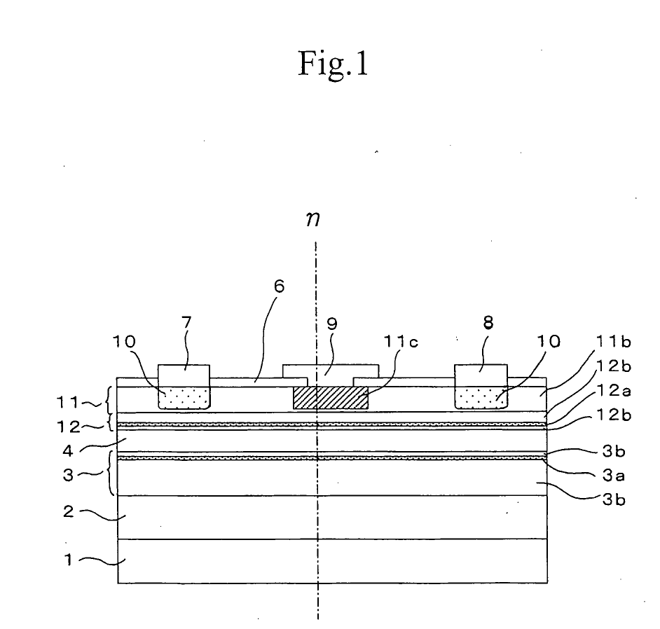

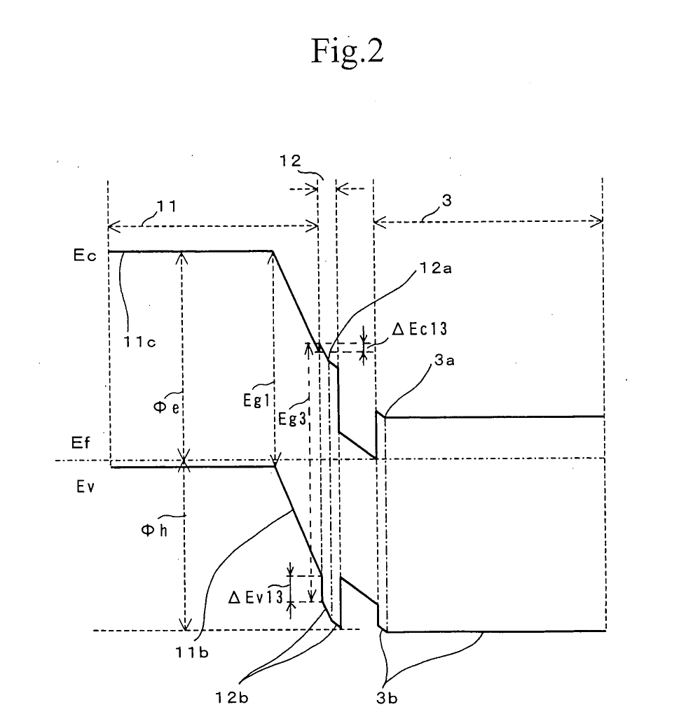

As one configuration capable of increasing φh without causing the above-described problems, there is proposed the first embodiment shown in FIG. 1. FIG. 2 shows a band diagram taken along η axis in FIG. 1. Differences from those shown in FIG. 7 and FIG. 8 are that the third barrier layer 12 composed of a semiconductor is inserted between the first barrier layer 11 composed of a semiconductor containing a p-type conductive region 11c and the channel layer 4. As shown in FIG. 2, the third barrier layer 12 has a band gap larger than that of the first barrier layer 11, so that energy difference ΔEv₁₃ between the valence band edges of the first barrier layer 11 and the third barrier layer 12 is larger than energy difference ΔEc₁₃ between the conduction band edges thereof. This results in larger φh and also successfully increases Vf, but the electron affinity of the third barrier layer 12 is not so reduced, and energy difference ΔEc₁₃ between the conduction band edges of the first and third barrier layers is not so much increased, thereby successfully preventing the source ohmic contact resistance from increasing. This configuration is also advantageous in no more causing the problem of Zn diffusion rate, because the Zn diffusion layer composing the p-type conductive region 11c can be configured so as not to reach the third barrier layer 12.

Relation between the first barrier layer 11 and the third barrier layer 12 is expressed by the relation below:
χ₁−χ₃≦0.5*(Eg₃−Eg₁) (1)
where χ₁ is electron affinity of the first barrier layer 11, Eg₁ is a band gap of the same, χ₃ is electron affinity of the third barrier layer 12, and Eg₃ is a band gap of the same.

The following paragraphs will specifically describe the first embodiment of the semiconductor device of the present invention referring to FIG. 1. The semiconductor device shown in FIG. 1 is typically configured so that, on one surface of the substrate 1 composed of semi-insulating single crystal GaAs, the second barrier layer 3 composed of AlGaAs having an Al composition ratio of 20% or around, the channel layer 4 composed of InGaAs having an In composition ratio of 20% or around, the third barrier layer 12 composed of InGaP, and the first barrier layer 11 composed of AlGaAs having an Al composition ratio of 20% or around are stacked in this order, while placing in between a buffer layer 2 composed of u-GaAs, u-AlGaAs or a multi-layered film of these, not intentionally doped with any impurities.

The first barrier layer 11 herein uses AlGaAs having an Al composition ratio of 20% or around, and the third barrier layer 12 herein uses InGaP, but combinations of the materials satisfying the relation (1) may include various combinations using III-V compound semiconductors containing at least any one of Ga, Al and In as a Group III element, and containing at least either one of As and P as a Group V element for the first barrier layer 11 and the third barrier layer 12. For the first barrier layer 11, GaAs, or AlGaAs having an Al composition ratio of 50% or less, or InGaP can typically be used. For the third barrier layer 12, in addition to InGaP and AlGaAs having an Al composition ratio of 50% or more, quaternary compounds such as AlInGaP and GaInAsP are also available. AlGaAs having an Al composition ratio of 50% or more can more readily satisfy the relation (1), because the electron affinity with respect to the X band in the conduction band grows larger. For the channel layer, GaAs is available besides InGaAs.

The first barrier layer 11 has the p-type conductive region 11c doped with a p-type impurity of high concentration and disposed under the gate electrode 9, and the rest of the region is given as a low-impurity-concentration region 11b. The p-type impurity used herein is Zn, by diffusion of which the p-type conductive region 11c is formed. Thickness of the first barrier layer 11 is set to 100 nm. Any thickness exceeding or smaller than this value may be permissible, but too large thickness makes it difficult to reduce the source contact resistance, and too small thickness makes it difficult to control the Zn diffusion, so that it is preferably set in a range from 70 to 100 nm or around. It may be difficult to exactly define the thickness of the low-impurity-concentration region for the case where addition of p-type impurity is carried out by the Zn diffusion, it is estimated as 90 nm or around assuming that the impurity concentration of the low-impurity-concentration region 11b is one-tenth or less of maximum concentration of the p-type impurity contained in the p-type conductive region 11c. In this case, the low-impurity-concentration region 11b of approximately 10 nm thick remains between the third barrier layer 12 and the p-type conductive region 11c. The thickness of the p-type conductive region 11c must appropriately be adjusted depending on a desired Vₜₕ because the total thickness of the low-impurity-concentration region 11b and the third barrier layer 12 determine the Vₜₕ, wherein a thickness of the low-impurity-concentration region 11b of 5 nm or more is preferable.

The third barrier layer 12 comprises an n-type impurity heavily-doped region 12a where n-type impurity such as Si is heavily doped and low-impurity-concentration regions 12b not intentionally doped with any impurities. In this example, the n-type impurity heavily-doped region 12a is 4 nm thick, the low-impurity-concentration region 12b disposed between the n-type impurity heavily-doped region 12a and the first barrier layer 11 is 3 nm thick, and the low-impurity-concentration region 12b disposed between the n-type impurity heavily-doped region 12a and the channel layer 4 is 3 nm thick, to thereby adjust the total thickness of the third barrier layer 12 to 10 nm. The third barrier layer 12 can be made thicker or thinner to some degree, but too large thickness raises another need of making the p-type conductive region also in the third barrier layer 12 in order to obtain a desired Vₜₕ adapted to the enhancement-mode operation, which may raise difficulty in controlling diffusion, so that a thickness of approximately 20 nm or less is preferable. Thickness of the n-type impurity heavily-doped region 12a is preferably adjusted to as small as possible, so far as a desired value of sheet concentration of an n-type impurity can be obtained, and so far as any difficulties in the manufacturing such as a lack of reproducibility, can be avoidable. The thickness is preferably set to several nanometers or less, and even may be that of mono-atomic layer. This is because product of mobility and carrier concentration in the channel layer between the source and the gate can be maximized, thereby the source resistance can be reduced, and also because the mobility degradation and the parallel conduction which is a carrier flow through the barrier layer can be suppressed in the gate region. Thickness of the low-impurity-concentration region 12b facing to the channel layer 4 is preferably 2 nm or more. This is for the purpose of suppressing degradation of the electron mobility in the channel layer 4.

The sheet impurity concentration of the n-type impurity heavily-doped region 12a herein was set to 2×10¹²/cm⁻². Too small concentration results in increase in the source resistance, so that it is preferably set to the 1×10¹²/cm⁻² level.

Also the second barrier layer 3 comprises an n-type impurity heavily-doped region 3a where n-type impurity such as Si is heavily doped, and a low-impurity-concentration region 3b not intentionally doped with any impurities. Sheet impurity concentration of the n-type impurity heavily-doped region 3a herein was set to 1×10¹²/cm⁻².

Thickness of the channel layer 4 herein was set to 15 nm or around in consideration of InGaAs having an In composition ratio of 20% or around, but the In composition ratio and the film thickness can arbitrarily be varied provided that the thickness is within a critical layer thickness.

An insulating film 6, a source electrode 7, a drain electrode 8 and a gate electrode 9 can be formed similarly to those in the configuration shown in FIG. 7. For the insulating film 6, Si₃N₄ can typically be used. For the source electrode 7, the drain electrode 8 and the gate electrode 9, Ti/Pt/Au can typically be used.

Besides the merits owned by the conventional JPHEMT shown in FIG. 7, the first embodiment having the JPHEMT structure also gives a merit of further raising the Vf, and this facilitates the complete enhancement mode operation, disuses any negative power generation circuit or drain switch for configuring power amplifiers, and reduces size and cost of the power amplifiers. Raising Vf is also useful in improving the power-added efficiency under a predetermined low-distortion condition.

It is to be understood that the first embodiment is a basic structure of the present invention, wherein it is also allowable to insert another layer between the third barrier layer and the channel layer, between the first barrier layer and the gate electrode 9, and between the first barrier layer and the third barrier layer, to thereby add new effects.

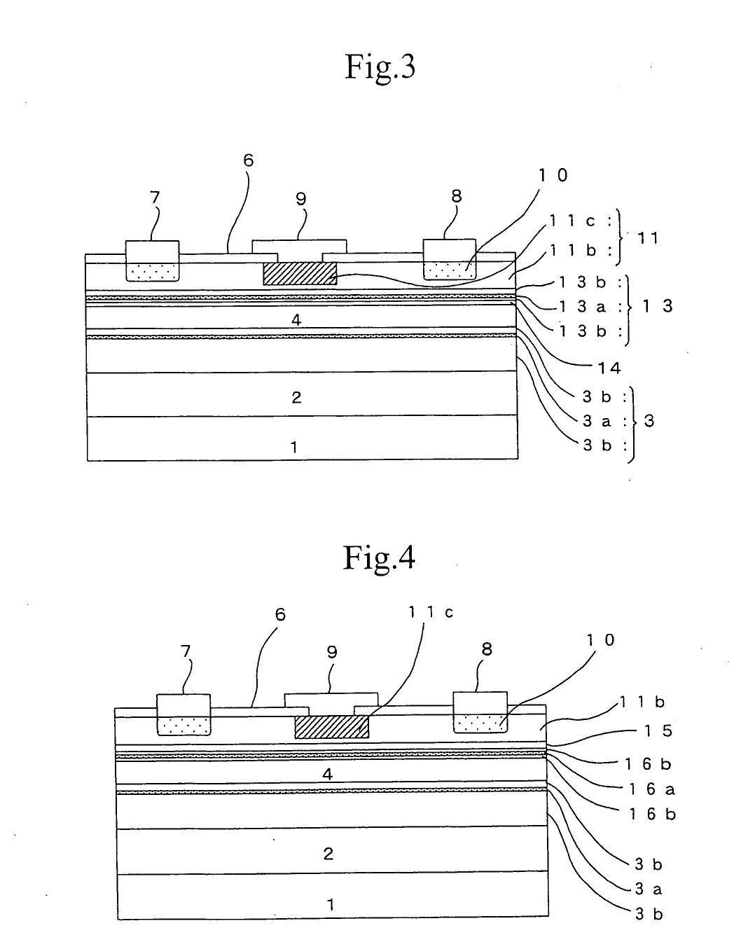

For example, in the first embodiment, the third barrier layer 12 has the n-type impurity heavily-doped region 12a heavily doped with an n-type impurity, but in some cases the n-type impurity cannot be added to a high concentration, or a desirable interface cannot be formed between the third barrier layer 12 and the channel layer 4, depending on species of the material used for the third barrier layer 12. In this case, a fourth barrier layer can conveniently be inserted between the third barrier layer and the channel layer 4. FIG. 3 shows a case (second embodiment) where the third barrier layer is doped with an n-type impurity to a high concentration, and FIG. 4 shows a case (third embodiment) where the fourth barrier layer is doped with an n-type impurity to a high concentration. The configuration shown in FIG. 4 is necessary for the case where an n-type impurity cannot readily be added to the third barrier layer at a high concentration, whereas either the configuration shown in FIG. 3 or FIG. 4 is allowable for the case where the interface between the third barrier layer and the channel layer 4 is a primary concern.

### Second Embodiment

The next paragraphs will describe the second embodiment of the semiconductor device of the present invention referring to FIG. 3. In comparison with the first embodiment, this embodiment further comprises a fourth barrier layer 14 not intentionally doped with any impurities, between the third barrier layer 13 and the channel layer 4.

The third barrier layer 13 uses a material satisfying the relation (1) with the first barrier layer 11, similarly to the third barrier layer 12 in the first embodiment, and comprises an n-type impurity heavily-doped region 13a where n-type impurity such as Si is heavily doped, and low-impurity-concentration regions 13b not intentionally doped with any impurities.

The fourth barrier layer 14 uses a material capable of forming a desirable interface with the channel layer 4, which is typically AlGaAs having an Al composition ratio of, for example, 20% or around or less, or GaAs, not intentionally doped with any impurities. In this case, too large distance of the n-type impurity heavily-doped region 13a away from the channel layer 4 may raise problems such as decrease in the carrier concentration and increase in the source resistance in the channel layer 4 between the source and the gate, and such that parallel conduction, characterized by carrier flow in the barrier layer, is more likely to occur in the gate region, so that thickness of the fourth barrier layer 14 is preferably set to 5 nm or below. Total thickness of the third barrier layer 13 and the fourth barrier layer 14 is preferably set to approximately 20 nm or less. Any portions other than those described in the above are formed similarly to those described in the first embodiment.

As described in the above, the second embodiment is successful in solving the problem of difficulty in forming a desirable interface between the third barrier layer 13 and the channel layer 4, by disposing the fourth barrier layer 14 therebetween.

### Third Embodiment

The following paragraphs will describe the third embodiment of the semiconductor device of the present invention referring to FIG. 4. In comparison with the first embodiment, this embodiment does not have a region heavily doped with an n-type impurity in a third barrier layer 15, and further comprises, as being disposed between the third barrier layer 15 and the channel layer 4 a fourth barrier layer 16 having an n-type impurity heavily-doped region 16a.

The third barrier layer 15 again uses a material satisfying the relation (1) with the first barrier layer 11, similarly to the third barrier layer 12 in the first embodiment, but is not intentionally doped with an n-type impurity.

On the other hand, the fourth barrier layer 16 uses a material capable of forming a desirable interface with the channel layer 4 similarly to the second embodiment, such as AlGaAs having an Al composition ratio of approximately 20% or less, or GaAs for example, and typically comprises an n-type impurity heavily-doped region 16a heavily doped with an n-type impurity, which is Si for example, and a low-impurity-concentration region 16b not intentionally doped with any impurities. The explanations same with those for the third barrier layer 12 of the first embodiment will apply to a thickness of the n-type impurity heavily-doped region 16a, a sheet concentration of the n-type impurity, and a thickness of the low-impurity-concentration region 16b on the channel layer 4 side, wherein it is preferable to set a total thickness of the third barrier layer 15 and the fourth barrier layer 16 to approximately 20 nm or less. Any portions other than those described in the above are formed similarly to as described in the first embodiment.

As described in the above, the third embodiment adopts the fourth barrier layer 16, and this is successful in making use of any materials for the third barrier layer 15 less likely to form a desirable interface with the channel layer 4 or less readily to be doped with an n-type impurity, so far as they satisfy the relation (1) with the first barrier layer 11.

### Fourth Embodiment

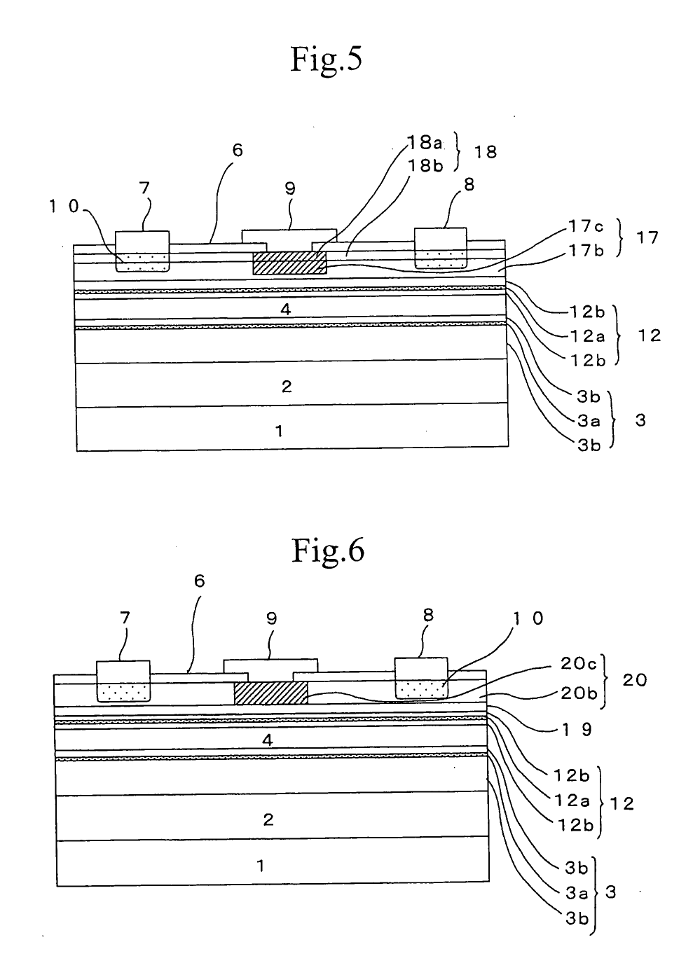

The first embodiment may sometimes raise a problem in ohmic contact resistance between the first barrier layer 11 and the gate electrode 9. In this case, it is advantageous to dispose, on the gate electrode side as shown in FIG. 5, a fifth barrier layer 18 composed of a semiconductor which has a sum of the electron affinity and the band gap smaller than that of the first barrier layer 17.

The following paragraphs will describe the semiconductor device of the fourth embodiment of the present invention. In this embodiment in comparison with the first embodiment, the first barrier layer 11 is altered to a two-layered configuration comprising a first barrier layer 17 and a fifth barrier layer 18, wherein the fifth barrier layer 18, which is composed of a semiconductor having a sum of the electron affinity and the band gap smaller than that of the first barrier layer 17 is disposed between the first barrier layer 17 and the gate electrode 9.

The fifth barrier layer 18 may typically be composed of GaAs, and contains, similarly to the first barrier layer 17, a p-type conductive region 18a which is heavily doped with a p-type impurity (Zn herein) under the gate electrode 9, and a region other than the p-type conductive region 18a is a low-impurity-concentration region 18b not intentionally doped with any impurities. Thickness of the fifth barrier layer 18 may typically set to 50 nm or around. Any portions other than those described in the above are similar to those described in the first embodiment.

As described in the above, the fourth embodiment makes it possible to reduce a Schottky barrier height between the gate metal and the semiconductor in contact with the gate metal, and thereby to lower the ohmic contact resistance, by disposing the fifth barrier layer having a sum of the electron affinity and the band gap smaller than that of the first barrier layer, between the gate electrode and the first barrier layer.

### Fifth Embodiment

The fifth embodiment of the semiconductor device of the present invention will be explained referring to FIG. 6. In this embodiment in comparison with the first embodiment, the first barrier layer 11 is altered to a two-layered configuration comprising a sixth barrier layer 19 and a first barrier layer 20 in view of enhancing the controllability of the Zn diffusion, wherein the sixth barrier layer 19, which is composed of a semiconductor in which the Zn diffusion rate is slower than in the first barrier layer 20, is disposed between the first barrier layer 20 and the third barrier layer 12.

In this configuration, AlGaAs or InGaP can typically be used for the first barrier layer 20, and GaAs or AlGaAs can typically be used for the sixth barrier layer 19. For the purpose of raising the Vₜₕ, the total thickness of the sixth barrier layer 19 and the third barrier layer 12 is preferably set to approximately 25 nm or less. It is also preferable for the sixth barrier layer to have a thickness of approximately 5 nm or more, so as to prevent Zn from penetrating the sixth barrier layer 19. Any portions other than those described in the above are similar to those described in the first embodiment.

As described in the above in the fifth embodiment, it is made possible, for the case where the p-type conductive region 20c of the first barrier layer 20 under the gate electrode 9 is formed by diffusing Zn, to block the Zn diffusion by the sixth barrier layer 19, and to thereby readily control the thickness of the Zn diffusion layer.

The semiconductor device of the present invention is by no means limited to the above-described embodiments, but allows various configurations based on combinations of the above-described embodiments. For example, only one or two, or all of the fourth to sixth barrier layers may exist.

As described in the above, the invention (1) is successful in effectively raising the gate-source forward turn-on voltage vf, by disposing the third barrier layer having the relation (1) between the first barrier layer and the channel layer, and therefore in realizing a power transistor which is capable of complete enhancement-mode operation and is excellent in the low-distortion, high-efficiency performance. As a consequence, a power amplifier configured by using this transistor disuses a negative power generation circuit and a drain switch, is reduced in the size and cost, and also becomes excellent in low-distortion, high-efficiency performance.

According to the invention (2), it is made possible to select the material for the third barrier layer without concerning the interface quality with the channel layer, by disposing the fourth barrier layer between the third barrier layer and the channel layer.

According to the invention (3), it is made possible to lower the ohmic contact resistance by disposing the fifth barrier layer, having a band gap smaller than that of the first barrier layer, between the first barrier layer and the gate electrode.

According to the invention (4), it is made possible to improve the controllability of the Zn diffusion for forming the p-type conductive region, by disposing the sixth barrier layer in which the Zn diffusion rate is slower than in the first barrier layer, between the first barrier layer and the third barrier layer.

1. A semiconductor device having a source electrode, a drain electrode, a gate electrode disposed between the source electrode and the drain electrode, and a channel layer composed of a semiconductor which serves as a current path between the source electrode and the drain electrode, characterized by comprising:
a first barrier layer composed of a semiconductor having a p-type conductive region doped with a p-type impurity of high concentration under the gate,
a second barrier layer disposed on an opposite side of said first barrier layer while placing said channel layer in between and is composed of a semiconductor having an electron affinity smaller than that of said channel layer, and
a third barrier layer disposed between said first barrier layer and said channel layer and is composed of a semiconductor having an electron affinity smaller than that of said channel layer, wherein a relation below:
χ₁−χ₃≦0.5*(Eg₃−Eg₁) (1)
is satisfied, where χ₁ is electron affinity of said first barrier layer, Eg₁ is a band gap thereof, χ₃ is electron affinity of said third barrier layer, and Eg₃ is a band gap thereof.

2. The semiconductor device as claimed in claim 1, characterized in that the semiconductor composing said third barrier layer is composed of a III-V compound semiconductor containing at least any one of Ga, Al and In as a Group III element, and containing at least either one of As and P as a Group V element.

3. The semiconductor device as claimed in claim 1, characterized in that the semiconductor composing said third barrier layer is InGaP or AlGaInP or InGaAsP.

4. The semiconductor device as claimed in claim 1, characterized in that the semiconductor composing said third barrier layer is AlGaAs or AlGaAsP or AlGaInAs, having an Al composition ratio of 50% or more.

5. The semiconductor device as claimed in claim 1, characterized in that a thickness of said third barrier layer is 20 nm or less.

6. The semiconductor device as claimed in claim 1, characterized in that the semiconductor composing said first barrier layer is AlGaAs or GaAs or InGaP.

7. The semiconductor device as claimed in claim 1, characterized by having a fourth barrier layer composed of a semiconductor having an electron affinity smaller than that of said channel layer and disposed between said third barrier layer and said channel layer.

8. The semiconductor device as claimed in claim 7, characterized in that the semiconductor composing said fourth barrier layer is AlGaAs or GaAs.

9. The semiconductor device as claimed in claim 7, characterized in that a sum of thicknesses of said third barrier layer and said fourth barrier layer is 20 nm or less.

10. The semiconductor device as claimed in claim 1, characterized by having a fifth barrier layer composed of a semiconductor having a band gap smaller than that of the first barrier layer and having a p-type conductive region doped with a p-type impurity of a high concentration, disposed between said first barrier layer and said gate electrode.

11. The semiconductor device as claimed in claim 10, characterized in that the semiconductor composing said fifth barrier layer is GaAs.

12. The semiconductor device as claimed in claim 1, characterized in that the p-type impurity doped to said first barrier layer is Zn.

13. The semiconductor device as claimed in claim 1, characterized by having a sixth barrier layer composed of a semiconductor in which a Zn diffusion rate is slower than in the first barrier layer, disposed between said first barrier layer and said third barrier layer.

14. The semiconductor device as claimed in claim 13, characterized in that the semiconductor composing said sixth barrier layer is GaAs or AlGaAs.

15. The semiconductor device as claimed in claim 13, characterized in that a sum of thicknesses of said third barrier layer and said sixth barrier layer is 25 nm or less.

16. The semiconductor device as claimed in claim 1, characterized in that, in a semiconductor layer on a gate electrode side in contact with said third barrier layer, a semiconductor layer which contains only one-tenth or less impurity as compared with a maximum impurity concentration of the p-type impurity contained in said first barrier layer exists in a thickness of 5 nm or more.

17. The semiconductor device as claimed in claim 1, characterized in that at least any one layer of said first barrier layer, third barrier layer, fourth barrier layer and sixth barrier layer is doped with n-type impurity of high concentration.

18. The semiconductor device as claimed in claim 1, characterized in that the semiconductor composing said channel layer is InGaAs or GaAs.
